(19) United States
(12) Patent Application Publication
(10) Pub. No.: US 2012/0208130 A1
(43) Pub. Date: Aug. 16, 2012

(54) METHOD FOR MANUFACTURING STRUCTURE

(75) Inventor: Takahiko YOSHIZAWA, Sakata-shi (JP)

(73) Assignee: SEIKO EPSON CORPORATION, Tokyo (JP)

(21) Appl. No.: 13/354,887

(22) Filed: Jan. 20, 2012

(30) Foreign Application Priority Data
Feb. 10, 2011 (JP) 2011-026870

(51) Int. Cl. G03F 7/22

(52) U.S. Cl. 430/323; 430/325

(57) ABSTRACT

A method for manufacturing a structure includes forming a layer of photosensitive material above a substrate, disposing a mask above the layer of photosensitive material, shielding a portion of the layer of photosensitive material other than a first region of the layer of photosensitive material, exposing the first region, moving the mask along a surface of the layer of photosensitive material, shielding a portion of the layer of photosensitive material other than a second region that is a portion of the first region and a third region that is adjacent to the second region and is a portion of the region shielded in the step, and exposing the second region and the third region, and developing the layer of photosensitive material to form surfaces in the layer of photosensitive material at different heights along a direction in which the mask is moved.

The entire disclosure of Japanese Patent Application No. 2011-026870, filed Feb. 10, 2011 is expressly incorporated by reference herein.

### BACKGROUND

1. Technical Field

The present invention generally relates to a method for manufacturing a micro structure having surfaces at different heights.

2. Related Art

Spectrum sensors are used in the medical, agricultural and environmental fields for diagnosing and examining objects. For example, in the medical field, a pulse oximeter is used to measure the oxygen saturation of blood, using light absorption of hemoglobin. Also, in the agricultural field, a saccharometer is used to measure the concentration of sugar content of fruits, using light absorption of sugar.

Japanese Laid-open Patent Application HEI 6-129908 (related art) describes a spectroscopic imaging sensor that controls incident angles of light with an optical fiber that optically connects interference filters and photovoltaic converter elements, thereby restricting the transmission wavelength bandwidth of light to the photovoltaic conversion elements. However, miniaturization of such a spectrum sensor by the related art is difficult.

For example, for manufacturing a small-size spectrum sensor, micro sloped structures need to be formed. However, it has been difficult to manufacture such micro structures according to the related art.

### SUMMARY

The invention has been made in view of the technical difficulty described above. An aspect of the invention pertains to providing a manufacturing method that makes it possible to manufacturing micro structures having surfaces at different heights.

In accordance with an embodiment of the invention, a method for manufacturing a structure includes the steps of: (b) forming a layer of photosensitive material above a substrate; (c) disposing a mask above the layer of photosensitive material; (d) shielding a portion of the layer of photosensitive material other than a first region of the layer of photosensitive material, and exposing the first region; (e) moving the mask along a surface of the layer of photosensitive material; (f) shielding a portion of the layer of photosensitive material other than a second region that is a portion of the first region and a third region that is adjacent to the second region and is a portion of the region shielded in the step (d), and exposing the second region and the third region; and (g) developing the layer of photosensitive material to form surfaces in the layer of photosensitive material at different heights along a direction in which the mask is moved. According to the aspect described above, a micro structure having surfaces at different heights can be readily manufactured with a process having high affinity to a semiconductor device fabrication process.

In accordance with an aspect of the embodiment described above, the method may preferably further include the step of (h) baking the layer of photosensitive material, after the step (g). According to this aspect, even when step differences are formed in the layer of photosensitive material in the step (g), smooth sloped surfaces or curved surfaces can be formed.

In accordance with an aspect of the embodiment described above, the method may preferably further include the step of (i) anisotropically etching the layer of photosensitive material and the substrate after the step (h), thereby forming surfaces at different heights along the direction in which the mask is moved. According to the aspect, sloped surfaces or curved surfaces can be readily formed in the substrate.

In accordance with an aspect of the embodiment described above, the method may preferably further include the step of (a) of forming an intermediate layer above the substrate before the step (b), and the step of (i) anisotropically etching the layer of photosensitive material and the intermediate layer after the step (g), thereby forming surfaces at different heights in the intermediate layer along the direction in which the mask is moved, and the layer of photosensitive material may preferably be formed above the intermediate layer in the step (b). According to the aspect described above, slopes surfaces or curved surfaces can be readily formed in the intermediate layer on the substrate.

In accordance with an aspect of the embodiment described above, the mask may preferably have a shape for forming the first region such that a boundary line of the first region includes a linear line traversing the direction in which the mask is moved. According to this aspect, a micro structure having a desired slope angle can be readily manufactured.

In accordance with an aspect of the embodiment described above, the layer of photosensitive material may be exposed to light while the mask is moved along the surface of the layer of photosensitive material in the step (e). According to this aspect, sloped surfaces or curved surfaces can be formed in the layer of photosensitive material.

### BRIEF DESCRIPTION OF THE DRAWINGS

FIGS. 1A and 1B are a cross-sectional view and a plan view showing a method for manufacturing a structure in accordance with an embodiment of the invention.

FIGS. 2A and 2B are a cross-sectional view and a plan view showing the method for manufacturing a structure in accordance with the embodiment of the invention.

FIGS. 3A and 3B are a cross-sectional view and a plan view showing the method for manufacturing a structure in accordance with the embodiment of the invention.

FIGS. 4A and 4B are a cross-sectional view and a plan view showing the method for manufacturing a structure in accordance with the embodiment of the invention.

FIGS. 5A and 5B are a cross-sectional view and a plan view showing the method for manufacturing a structure in accordance with the embodiment of the invention.

FIGS. 6A and 6B are a cross-sectional view and a plan view showing the method for manufacturing a structure in accordance with the embodiment of the invention.

FIGS. 7A and 7B are a cross-sectional view and a plan view showing the method for manufacturing a structure in accordance with the embodiment of the invention.

FIGS. 8A and 8B are a cross-sectional view and a plan view showing the method for manufacturing a structure in accordance with the embodiment of the invention.

FIGS. 9A and 9B are a cross-sectional view and a plan view showing the method for manufacturing a structure in accordance with the embodiment of the invention.

FIGS. 10A and 10B are a cross-sectional view and a plan view showing the method for manufacturing a structure in accordance with the embodiment of the invention.

FIG. 11 is a cross-sectional view schematically showing the structure of a spectrum sensor using the structure in accordance with the embodiment of the invention.

### DESCRIPTION OF EXEMPLARY EMBODIMENTS

Embodiments of the invention are described in detail below. It is noted that the embodiments described below do not unduly limit the contents of the invention set forth in the scope of patent claims. Also, not all of the compositions described in the embodiments would necessarily be essential for the solution provided by the invention. Furthermore, the same components will be appended with the same reference numbers, and their description will not be repeated.

1. Method For Manufacturing Sloped Structure

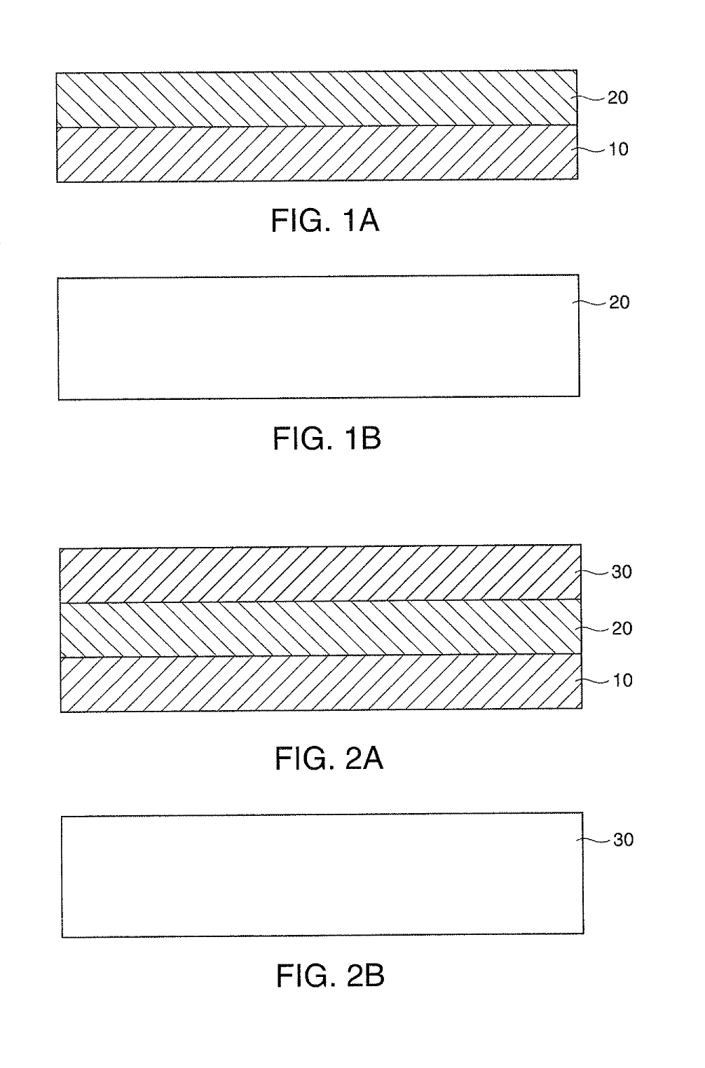

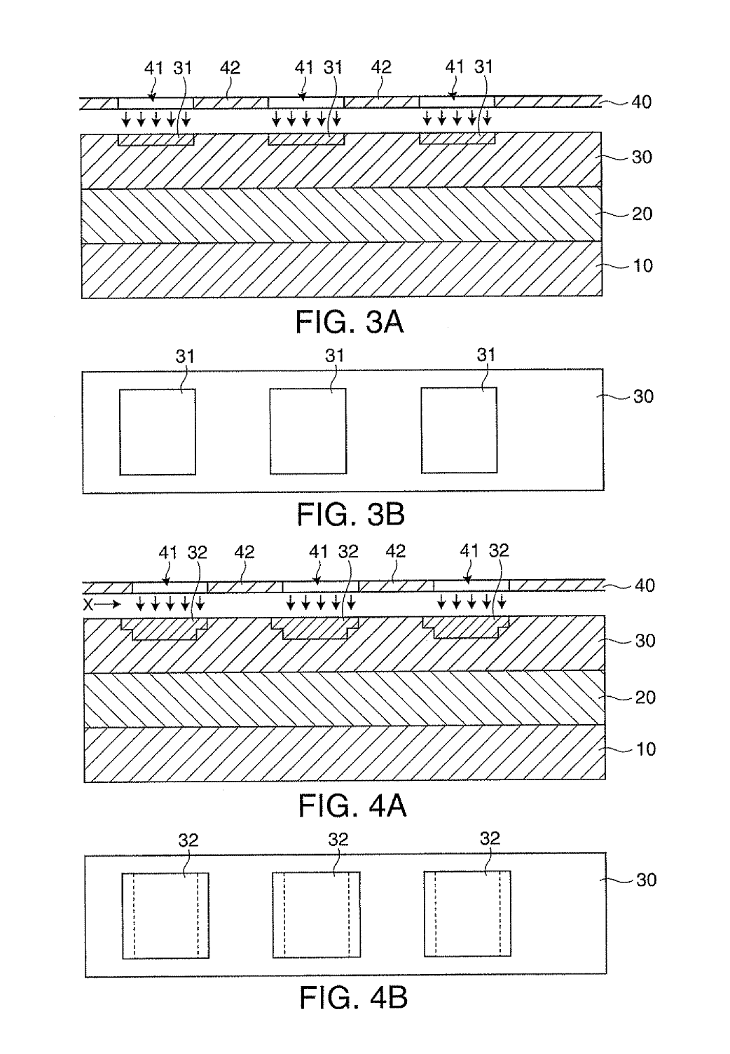

FIGS. 1 through 10 are cross-sectional views and plan views showing a method for manufacturing a structure in accordance with an embodiment of the invention. It is noted that, in each of the plan views in FIGS. 3 through 7, the illustration of a mask is omitted. According to the present embodiment, a method for manufacturing a structure having sloped surfaces is shown. The manufacturing method in accordance with the present embodiment can readily achieve cost reduction and device miniaturization, as the method uses a semiconductor processing technology.

1-1. Layer Lamination

First, as shown in FIGS. 1A and 1B, an intermediate layer 20 that becomes to be a structure having sloped surface is formed on a substrate 10. Dielectric material or conductive material may be used as the material of the intermediate layer 20 depending on properties required by the structure having sloped surfaces. As the dielectric material, SiOF, PSG (phosphosilicate glass), BPSG (borophosphosilicate glass), SiO₂, SiN, and organic films may be used. As the conductive material, Al, Au, Co, Cr, Cu, Mo, Ni, Pt, Ta, Ti, W, Al—Cu alloys, Al—Si—Cu alloys, Si, WSi₂, TiSi₂, CoSi₂, NiSi₂, CrSi₂, MoSi₂, TaSi₂, TaN and TiN may be used.

Next, as shown in FIGS. 2A and 2B, a layer of photosensitive material 30 is formed on the intermediate layer 20. As the material for the layer of photosensitive material 30, for example, a positive type photosensitive material may be used, but a negative type photosensitive material may also be used. As the layer of photosensitive material 30, novolac type resist, KrF excimer resist, ArF excimer resist or the like may be used. The layer of photosensitive material 30 does not require high ON/OFF sensitivity, and may have a property with which sloped surfaces can be formed with patterns formed at the time of development and having different depths that very depending on the amount of exposed light.

1-2. Exposure

Next, as shown in FIGS. 3A and 3B, a mask 40 is placed between the layer of photosensitive material 30 and a light source for exposure. The mask 40 is formed with a transmissive section 41 that transmits exposure light, and a shield section 42 that does not transmit exposure light. Then, exposure light is irradiated on the layer of photosensitive material 30 through the mask 40. By this, a latent image 31 having a shape corresponding to the shape of the transmission section 41 is formed in the surface of the layer of photosensitive material 30. The light intensity and the irradiation time of the exposure light to be irradiated are set such that the layer of photosensitive material 30 would not be sensitized through the entire thickness.

Next, as shown in FIGS. 4A and 4B, the mask 40 is slightly moved along the surface of the layer of photosensitive material 30 (in the direction of an arrow X), and exposure light is irradiated on the layer of photosensitive material 30 through the mask 40. Here, the mask 40 is moved by a distance that is shorter than the length of the transmission section 41 in the moving direction of the mask 40. By this, a portion (a second region) of the area where the latent image 31 is formed (i.e., a first region) in the step shown in FIG. 3A and a portion of the area that is shielded (i.e., a third region) in the step shown in FIG. 3A and is adjacent to the second region are exposed. As a result, a latent image 32 is formed in the surface of the layer of photosensitive material 30. The latent image 32 is formed to a deeper level in the layer of photosensitive material 30 in the second region that is exposed in both of the steps in FIG. 3A and FIG. 4A, and to a shallower level in the layer of photosensitive material 30 in the first region and the third region that are exposed only in one of the steps in FIG. 3A and FIG. 4A.

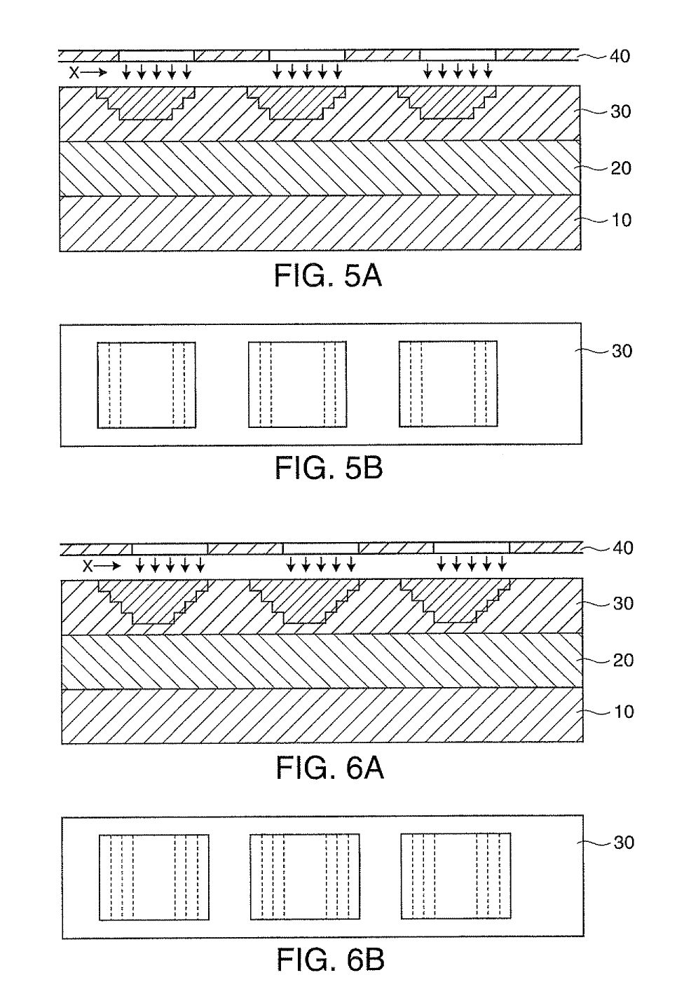

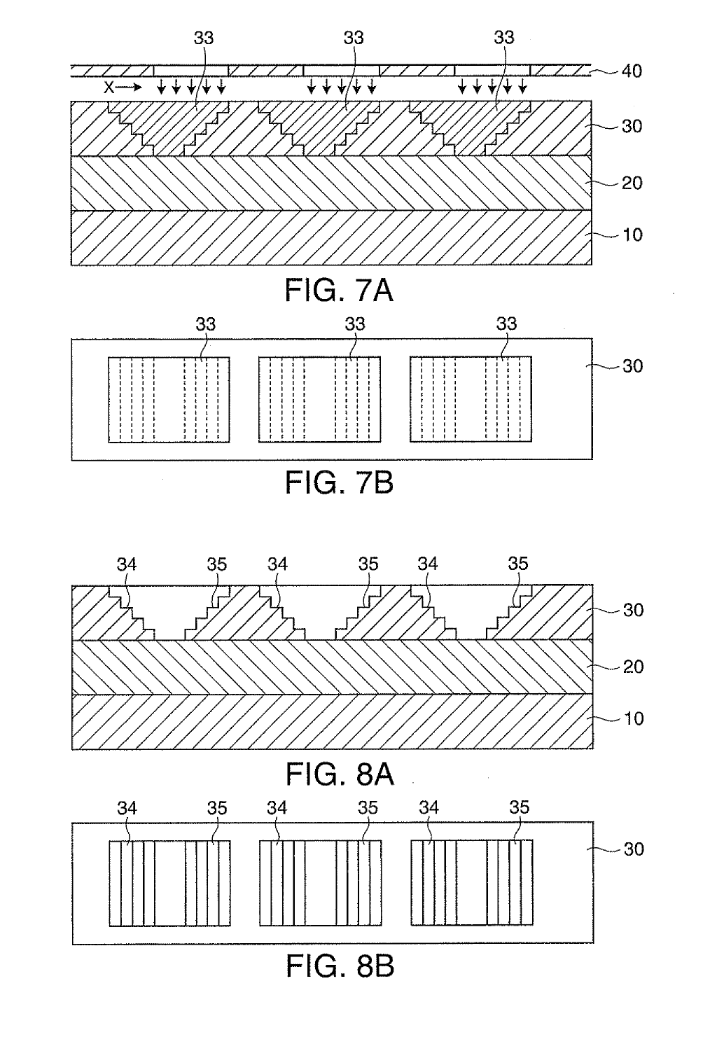

Next, as shown in FIGS. 5 through 7, exposure light is irradiated each time the mask 40 is moved. By this operation, the greater the number of times of irradiation of exposed light in a portion in the layer of photosensitive material 30, the deeper the latent image is formed in that portion; and the fewer the number of times of irradiation of exposed light in a portion in the layer of photosensitive material 30, the shallower the latent image is formed in that portion. As a result, as shown in FIG. 7A, a latent image 33 in a stepwise fashion having different depths from the top surface of the substrate 10 is formed along the moving direction X of the mask 40.

Here, the embodiment is described above as to the case where moving of the mask 40 and irradiation of the exposure light are alternately conducted; while the mask 40 is moved, the exposure light is not irradiated; and while the exposure light is irradiated, the mask 40 is not moved. However, the invention is not limited to the embodiment described above. The exposure light may be irradiated while the mask 40 is moved, and the mask 40 may be moved while the exposure light is irradiated. Also, in the example shown above, the shape of the transmission section 41 (the shape of the latent image 31) is rectangular. However, without any particular limitation to the above, the transmission section 41 may be in any shape as long as the boundary line of the transmission section 41 includes a linear line in a direction transverse to the moving direction X of the mask 40.

The longer the transfer distance of the mask 40 at each irradiation of the exposure light, the gentler the slope of the latent image 33 becomes; and the shorter the transfer distance of the mask 40 at each irradiation of the exposure light, the steeper the slope of the latent image 33 becomes. In this respect, the slope angle of the structure having the sloped surface can be adjusted. In the illustrated example, the latent image 33 is formed in a stepwise fashion. However, the invention is not limited to the above. By moving the mask 40 during irradiation of the exposure light, the stepwise sloped surface can be smoothed. Also, in the course of the steps shown in FIGS. 3 through 7, the transfer distance of the mask 40 at each irradiation of the exposure light may be changed, whereby a structure having a curved surface can be fabricated. Also, the latent image 33 may not have to be in contact with the intermediate layer 20. Also, a plurality of regions having different exposure conditions may be provided on a single substrate, such that structures having sloped surfaces having different slope angles can be formed on the single substrate.

1-3. Development

Next, as shown in FIGS. 8A and 8B, the layer of photosensitive material 30 is developed. When the layer of photosensitive material 30 is composed of a positive type material, portions corresponding to the latent image 33 shown in FIGS. 7A and 7B are removed by the development, such that sloped surfaces are formed in the layer of photosensitive material 30. The sloped surfaces include portions 34 that become deeper in the transfer direction of the mask 40, and portions 35 that become shallower in the transfer direction of the mask 40.

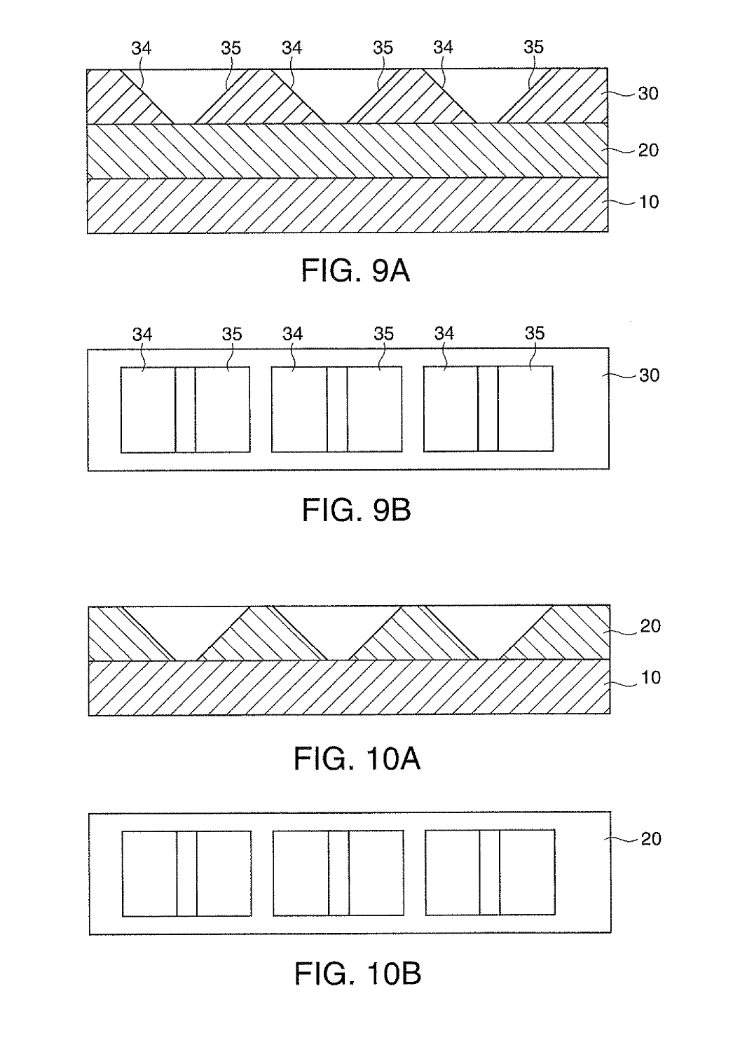

Next, as shown in FIGS. 9A and 9B, the substrate 10 is heated to bake the layer of photosensitive material 30. By this, the stepwise sloped surfaces 34 and 35 change into smooth sloped surfaces 34 and 35. The surfaces at different heights refer to the stepwise sloped surfaces and the smooth sloped surfaces. Lastly, as shown in FIGS. 10A and 10B, the layer of photosensitive material 30 and the intermediate layer 20 are etched. The etching may preferably be an anisotropic etching that etches the layer in a vertical direction to the surface of the substrate 10, and may preferably be a dry etching. By this, the layer of photosensitive material 30 is removed, and a sloped structure similar to the sloped structure formed in the layer of photosensitive material 30 is formed in the intermediate layer 20. It is noted that, without forming the intermediate layer 20, the layer of photosensitive material 30 may be formed directly on the substrate 10, and the sloped structure formed in the layer of photosensitive material 30 may be used to form the sloped structure on the substrate 10.

1-4. Effect of Embodiment

According to the manufacturing process described above, a structure having sloped surfaces or curved surfaces can be fabricated, using technologies having high affinity to a semiconductor device fabrication process, such as, film formation, exposure, development, etching and the like. Accordingly, the embodiment makes it easier to mix and mount a structure having sloped surfaces or curved surfaces and a semiconductor circuit on a single chip. Also, the embodiment makes it unnecessary to fabricate metal molds that would be expensive and quickly worn out, and makes it unnecessary to refabricate metal molds for changing the shape of the structure. Further, according to the manufacturing process described above, structures having micro sloped surfaces or curved surfaces can be fabricated not only with materials that can be formed by a metal mold (such as, for example, resins), but also with a variety of other materials. Moreover, the mask that is used in the fabrication process described above does not need to have a special structure, such as, that of a grayscale mask. Also, according to the fabrication process described above, required sloped surfaces or curved surfaces can be formed at any required locations within a limited space on a substrate.

2. Spectrum Sensor

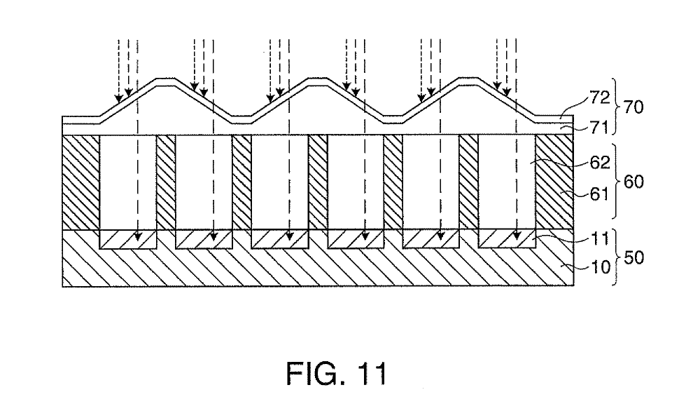

FIG. 11 is a cross-sectional view schematically showing the structure of a spectrum sensor using a structure in accordance with an embodiment of the invention. The spectrum sensor shown in FIG. 11 includes an optical device section 50 having photo detector elements, an angle restriction filter section 60, and a spectrum filter section 70.

The optical device section 50 is equipped with a substrate 10 formed from semiconductor material such as silicon, and photodiodes 11 formed in the substrate 10. Further, the substrate 10 includes an electronic circuit (not shown) formed thereon to perform various operations, such as, applying a predetermined reverse bias voltage to the photodiodes 11, detecting a current based on photoelectric power generated at the photodiodes 11, amplifying analog signals according to the magnitude of the current, and converting the analog signals to digital signals.

2-1. Angle Restriction Filter Section

The angle restriction filter section 60 is formed above the substrate 10. The angle restriction filter section 60 includes a shield section 61 that forms optical path walls, and optical paths are formed by transmissive material 62 such as silicon oxide or the like surrounded by the optical path walls. The shield section 61 is formed from material that does not substantially transmit light having wavelengths to be received by the photodiodes 11. The shield section 61 may be formed with a plurality of layers in, for example, a predetermined lattice pattern sequentially deposited on the substrate 10, whereby the optical paths are formed in a direction perpendicular to the surface of the substrate 10.

The incident angle of light passing through the optical paths is restricted by the angle restriction filter section 60. More specifically, when light entered the optical paths is inclined more than a predetermined restriction angle with respect to the direction of the optical paths, the light hits the shield section 61, a portion of the light is absorbed by the shield section 61, and the remaining portion is reflected. The reflection is repeated and the reflected light becomes weaker while the light is passing through the optical paths. Accordingly, light that can pass the angle restriction filter section 60 is substantially limited to light that enters the optical paths at inclinations less than the predetermined restriction angle with respect to the optical paths.

2-2. Spectrum Filter Section

The spectrum filter section 70 includes a sloped structure 71 formed on the angle restriction filter section 60, and a multilayer film 72 formed on the sloped structure 71. The multilayer film 72 is formed from thin films of a low refractive index material such as silicon oxide and thin films of a high refractive index material such as titanium oxide, laminated in multiple layers, and slightly inclined with respect to the substrate 10. The thin films of a low refractive index and the thin films of a high refractive index each have a predetermined film thickness, for example, on the order of submicron, and are laminated, for example, in about 60 layers in total, such that the entire multilayer film 72 is, for example, about 6 μm in thickness.

The angle of inclination of the multilayer film 72 with respect to the substrate 10 may be set, for example, between 0 degree and 30 degrees, according to set wavelengths of light to be received by the photodiodes 11. In order to have the multilayer film 72 inclined with respect to the substrate 10, the sloped structure 71 having light transmissivity is formed on the angle restriction filter section 60, and the multilayer film 72 is formed on the sloped structure 71. As the sloped structure 71, a structure having sloped surfaces fabricated by the fabrication method described above may be used.

The spectrum filter section 70 having the structure described above restricts wavelengths of light incident on the angle restriction filter section 60 within the predetermined range of restricting angles. More specifically, a portion of incident light that has entered the spectrum filter section 70 becomes reflected light and another portion thereof becomes transmitting light at an interface between a set of the low refractive index thin film and the high refractive index thin film. Then, a portion of the reflected light reflects again at an interface between another set of the low refractive index thin film and the high refractive index thin film, and couples with the aforementioned transmitting light. In this instance, when light has a wavelength that matches with the optical path length of reflected light, the reflected light and the transmitting light match in phase with each other, and thus strengthen each other. When light has a wavelength that does not match with the optical path length of reflected light, the reflected light and the transmitting light do not match in phase with each other, and thus weaken each other (destructively interfere with each other).

Here, the optical path length of reflected light is determined by the angle of inclination of the multilayer film 72 with respect to the direction of the incident light. Accordingly, when the interference action described above is repeated in the multilayer film 72, which is formed from as many as 60 layers in total, light having only specific wavelengths can pass through the spectrum filter section 70, according to the incident angle of incident light, and is emitted from the spectrum filter section 70 at a predetermined emission angle (for example, at the same angle as the incident angle to the spectrum filter section 70).

The angle restriction filter section 60 allows only light incident on the angle restriction filter section 60 in the predetermined range of restriction angles to pass therein. Accordingly, the wavelengths of light that passes through the spectrum filter section 70 and the angle restriction filter section 60 are restricted to a predetermined range of wavelengths which is determined by the angles of inclination of the multilayer film 72 with respect to the substrate 10, and the range of restriction angles of incident light allowed to pass by the angle restriction filter section 60.

By forming in advance the sloped structures 71 having angles of inclination that differ depending on the set wavelengths of light to be received by the photodiodes 11, the multilayer film 72 can be formed in the same thickness by a common process, without regard to the set wavelengths of light to be received by the photodiodes 11.

2-3. Optical Device Section

The photodiodes 11 included in the optical device section 50 receive light that has passed through the spectrum filter section 70 and the angle restriction filter section 60, and convert the light to photovoltaic power. The photodiodes 11 include impurity regions formed by ion injection or the like in the substrate 10 that is composed of semiconductor material.

As light that has passed through the spectrum filter section 70 and the angle restriction filter section 60 is received by the photodiodes 11, photovoltaic power is generated, whereby an electric current is generated. By detecting the electric current by an electronic circuit (not shown), the light is detected.

2-4. Method for Manufacturing Spectrum Sensor

Here, a method for manufacturing the spectrum sensor is briefly described. The spectrum sensor is manufactured through initially forming the photodiodes 11 on the substrate 10, then forming the angle restriction filter section 60 on the photodiodes 11, and then forming the spectrum filter section 70 on the angle restriction filter section 60.

According to the present embodiment, spectrum sensors can be manufactured in one continuous operation by the semiconductor process, and spectrum sensors using the sloped structures having any desired angles of inclination can be readily formed. Also, by using multiple sloped structures having different angles of inclination, light with multiple wavelengths can be detected.

It is noted that the spectrum sensor described above is a transmission type spectrum sensor in which incident light passes through the spectrum filter section 70 and reaches the optical device section 50. However, the invention is also applicable to a reflection type spectrum sensor in which incident light reflects at the spectrum filter section 70, and reaches the optical device section. Also, as the device that uses the structure having sloped surfaces or curved surfaces, an optical sensor is described above. However, the structure having sloped surfaces or curved surfaces may be used as any one of other types of devices. For example, the structure may be used as an optical device, such as, a prism, a mirror or the like for relaying light signals with a predetermined wavelength in a relay device for optical fibers. Also, the structure having curved surfaces may be used as a micro lens array that is arranged with numerous micro lenses.

What is claimed is:

1. A method for manufacturing a structure, the method comprising the steps of:
(b) forming a layer of photosensitive material above a substrate;
(c) disposing a mask above the layer of photosensitive material;
(d) shielding a portion of the layer of photosensitive material other than a first region of the layer of photosensitive material, and exposing the first region;
(e) moving the mask along a surface of the layer of photosensitive material;
(f) shielding a portion of the layer of photosensitive material other than a second region that is a portion of the first region and a third region that is adjacent to the second region and is a portion of the region shielded in the step (d), and exposing the second region and the third region; and
(g) developing the layer of photosensitive material to form surfaces in the layer of photosensitive material at different heights along a direction in which the mask is moved.

2. The method for manufacturing a structure according to claim 1, further comprising:
(h) baking the layer of photosensitive material, after the step (g).

3. The method for manufacturing a structure according to claim 2, further comprising:
(i) anisotropically etching the layer of photosensitive material and the substrate after the step (h), thereby forming surfaces at different heights along the direction in which the mask is moved.

4. The method for manufacturing a structure according to claim 2, further comprising the steps of:
(a) forming an intermediate layer above the substrate before the step (b), and
(i) anisotropically etching the layer of photosensitive material and the intermediate layer after the step (g), thereby forming surfaces at different heights in the intermediate layer along the direction in which the mask is moved,
the layer of photosensitive material being formed above the intermediate layer in the step (b).

5. The method for manufacturing a structure according to claim 1, wherein the mask has a shape for forming the first region such that a boundary line of the first region includes a linear line traversing the direction in which the mask is moved.

6. The method for manufacturing a structure according to claim 1, wherein the layer of photosensitive material is exposed while the mask is moved along the surface of the layer of photosensitive material in the step (e).
